(19) United States
(12) Patent Application Publication
(10) Pub. No.: US 2011/0254611 A1
(43) Pub. Date: Oct. 20, 2011

(54) Connecting Apparatus for Field Device and Method for Operation

(75) Inventor: Hans VOLKMANN, Burgthann (DE)

(73) Assignee: Siemens Aktiengesellschaft, Munchen (DE)

(21) Appl. No.: 13/087,011

(22) Filed: Apr. 14, 2011

(30) Foreign Application Priority Data
Apr. 16, 2010 (EP) EP10160159

(51) Int. Cl. H03K 17/00; G01R 19/00

(52) U.S. Cl. 327/365; 324/76.11

(57) ABSTRACT

A connecting apparatus for field devices in an explosion-hazard zone, comprising an input terminal area for a first connecting line, an output terminal area for a second connecting line, a covering device for protecting at least one of the terminal areas, a first switching element for passing an electric current from the input terminal area to the output terminal area, a control unit for controlling the first switching element, a first sensor device that detects opening of the covering device, where the first sensor device is connected to the control unit and the control unit is configured to operate the first switching element.

### BACKGROUND OF THE INVENTION

1. Field of the Invention

The invention relates to a connecting apparatus for field devices in an explosion-hazard zone comprising an input terminal area for a first connecting line, an output terminal area for a second connecting line, a covering device for protection of at least one of the terminal areas, a first switching element for passing an electric current from the input terminal area to the output terminal area and a control unit for controlling the first switching element.

The invention furthermore relates to a method for operation of a connecting apparatus for field devices in an explosion-hazard zone, with the connecting apparatus being operated within a redundant communication ring with further connecting apparatuses, with a first connecting line being connected by an input terminal area and with a second connecting line being connected by an output terminal area to supply the connecting apparatus with current through a feed device within the communication ring, and with the covering device being provided for protection of at least one of the terminal areas.

2. Description of the Related Art

Connecting apparatuses for field devices are known from WO 2005/053221 A2. Reference is expressly made to WO 2005/053221 A2 with regard to the capability to implement the invention with respect to the connecting apparatuses for field devices during operation of a network, i.e., in a PROFIBUS PA network. The content of this document is hereby incorporated herein in its entirety.

The known branching elements or connecting apparatuses for field devices have the disadvantage that the devices such as a Profibus PA/Foundation Fieldbus (PA/FF bus), cannot be replaced easily during operation, i.e., during operation in an explosion-hazard zone. This is because it is permissible to replace connecting apparatuses in an explosion-hazard zone only when the lines are free of voltage and/or the maximum currents and voltages at the terminals are limited. In conventional connecting apparatuses, replacement of the connecting apparatus within the explosion-hazard zone is possible only when they are free of voltage, i.e., in the switched-off state. Further bus extension by such connecting apparatuses is therefore restricted. For example, a PA/FF bus allows voltages of 32 V and currents of more than 1 A. It is not permissible to connect and disconnect lines in the explosion-hazard zone when these voltages and currents are present.

### SUMMARY OF THE INVENTION

It is therefore an object of the invention to provide a connecting apparatus such that a bus construction, i.e., for a redundantly operated bus, can be configured to be more flexible.

This and other objects and advantage are achieved in accordance with the invention by providing a connecting apparatus having a first sensor device that detects opening of a covering device, where a first sensor device is connected to the control unit, and a control unit is configured to operate a first switching element. Connecting apparatuses that are operated within an explosion-hazard zone are subject to the requirement that the terminal areas for connecting lines must be provided with IP30 covers. It is therefore advantageous for it to be necessary to initially open the covering device, such as an IP30 cover, for deliberate manipulation of the connecting apparatuses, such as the connection and disconnection of connecting lines. This opening can be detected by a sensor device, and the current flow from the input terminal area to the output terminal area, or the current flow to the respective terminal area on which the cover has been opened can thus be switched off, thus preventing hazardous spark formation in the explosion-hazard area.

In a further advantageous embodiment, the connecting apparatus is provided with a first measurement device for measuring the electric current, where the measurement device is configured such that a determined first measured value can be compared with a limit value and undershooting of the limit value can be identified. The measurement device is furthermore configured such that the current flow between the input terminal area and the output terminal area can be interrupted independently of the detection performed by the first sensor device based on the limit value being undershot. It is an advantage of the detection of the undershooting of a limit value that, for example, when a further connecting apparatus is connected in a series circuit with the claimed connecting apparatus, opening of the covering device of the connecting apparatus can be detected in the further connecting apparatus. This means that, when the covering device is opened on the connecting apparatus, and the opening is therefore detected by the sensor device, and the current flow is therefore interrupted, current can also no longer flow in the connected further connecting apparatus.

In a further advantageous embodiment, the covering device includes a first covering device, which is arranged over the input terminal area, and a second covering device, which is arranged over the output terminal area. This is advantageous, for example, in one embodiment, in which a first connecting line is passed from the left to the connecting apparatus and a second connecting line leads away from the connecting apparatus to the right. For example, if the intention is to replace only one connecting line for the connecting apparatus, then it is advantageous to achieve freedom from voltage on that side by opening the respective covering device.

In order to achieve freedom from voltage on one side, it is advantageous for the first sensor device to be associated with the first cover device, and a second sensor device to be associated with the second covering device. Here, the connecting apparatus with its covering device is configured such that the second sensor device detects opening of the second covering device.

This freedom from voltage on one side is achieved by a second switching element arranged in series with the first switching element, with the second sensor device being connected to the control unit and with the control unit being configured to operate the second switching element.

Furthermore, the connecting apparatus is configured with a second measurement device for measuring the electric current, with the second measurement device being configured such that a determined second measured value can be compared with a limit value, and undershooting of the limit value can be identified, and is furthermore configured such that the current flow between the input terminal area and the output terminal area and the current flow between the output terminal area and the input terminal can be interrupted independently of the detection performed by the second sensor device based on of the limit value being undershot.

In order to correctly detect the opening of the cover means, it is recommended that the covering device is provided with a magnet that activates a Hall sensor. By way of example, the Hall sensor could be located directly on the printed circuit board of the device, in encapsulation on the device. A permanent magnet is accordingly located in the covering device, which comprises an IP30 cover flap, where the permanent magnet initiates a signal with the Hall sensor when the cover flap is opened, and this signal is evaluated by the control unit.

With regard to redundant operation of the connecting apparatus in a redundantly designed communication ring, i.e., when a plurality of connecting apparatuses are connected in series with one another and form a communication ring, it is worthwhile to disconnect the voltages and currents that are provided from both sides of the connecting apparatuses by at least one feed device.

It is therefore advantageous to also be able to switch the connected connecting line to an adjacent connecting apparatus to be free of voltage. No current can flow, because the cover flap is open and the switching element is thus operated. This is detected by the measurement device in the adjacent connecting apparatus, and is identified in the control unit. This connecting line from the adjacent connecting apparatus is therefore also switched to be free of voltage.

The initially mentioned object is likewise achieved by a method for operation of a connecting apparatus for field devices in an explosion-hazard zone. As mentioned initially, in accordance with the method, when the covering device is opened, the opening is detected and a first switching element is then opened, thus interrupting the current flow of the current from the input terminal area to the output terminal area.

The connecting apparatuses are operated in a series circuit with further connecting apparatuses, based on the connecting apparatuses being operated in a redundant communication ring. Consequently, for the connecting apparatus with the covering device open, the current flow to a predecessor connecting apparatus or to a successor connecting apparatus is changed. The changed current flow is measured in the predecessor connecting apparatus or the successor connecting apparatus and, if a limit value is undershot, the current flow of the current from the input terminal area to the output terminal area of the respective predecessor or successor or successor connecting apparatus is likewise interrupted. As a result, if the covering device of a connecting apparatus is operated to which a further connecting apparatus is connected in series on the left-hand side, and a further connecting apparatus is likewise connected in series on the right-hand side, on the one hand, the operation in the connecting apparatus with the open covering device results in a switching element being operated such that the current flow is interrupted. However, the operation and the interruption of the current flow result in this operation is likewise detected by measurement of the current, for example, in the predecessor connecting apparatus connected on the left-hand side, and the switching element in the predecessor connecting apparatus is likewise operated by a control unit in the predecessor connecting apparatus. As a result, the relevant connecting apparatus with the open cover flap is switched to be free of voltage on the left-hand side from the predecessor connecting apparatus.

For redundant operation, it is necessary for at least one feed device to be provided in the series circuit of a plurality of connecting apparatuses that are, in turn, joined together as a ring, and in this case, in accordance with the method, the connecting apparatuses are supplied from the side of their respective input terminal area, and from the side of their respective output terminal area.

In a further embodiment of the method, a first covering device is provided over the input terminal area and a second covering device is provided over the output terminal area. The opening of the first covering device opens the first switching element, and the opening of the second covering device opens the second switching element. Here, as a result of the undershooting of the limit value resulting from the opening of the switching elements, found by the measurement device arranged in the predecessor or successor connecting apparatus, the connecting apparatus with the open covering device is switched to be free of voltage on one side and/or on both sides, thus allowing work to be performed safely on the terminal areas.

Other objects and features of the present invention will become apparent from the following detailed description considered in conjunction with the accompanying drawings. It is to be understood, however, that the drawings are designed solely for purposes of illustration and not as a definition of the limits of the invention. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

One exemplary embodiment is described in more detail in the drawings, in which:

FIG. 1 is a schematic block diagram of a configuration of connecting apparatuses connected in series to form a redundant communication ring in accordance with the invention;

FIG. 2 is a connecting apparatus with connected field devices in accordance with the invention; and

FIG. 3 is a flow chart of the method in accordance with an embodiment of the invention.

### DETAILED DESCRIPTION OF THE PREFERRED EMBODIMENTS

As shown in FIG. 1, four connecting apparatuses 2 are connected in series with one another. The connecting apparatuses 2 all have the same reference symbols, since they are of identical design. Starting from a first feed device 1a, a first connecting apparatus is connected over a first connecting line T1. A second connecting apparatus is connected in series with the first connecting apparatus over a second connecting line T2. A third connecting apparatus and a fourth connecting apparatus are likewise connected in series with the second connecting apparatus. The fourth connecting apparatus is in turn connected to a second feed device 1b, with the first feed device 1a and the second feed device 1b likewise being connected. A redundant PA/FF bus is formed by this series connection comprising a ring.

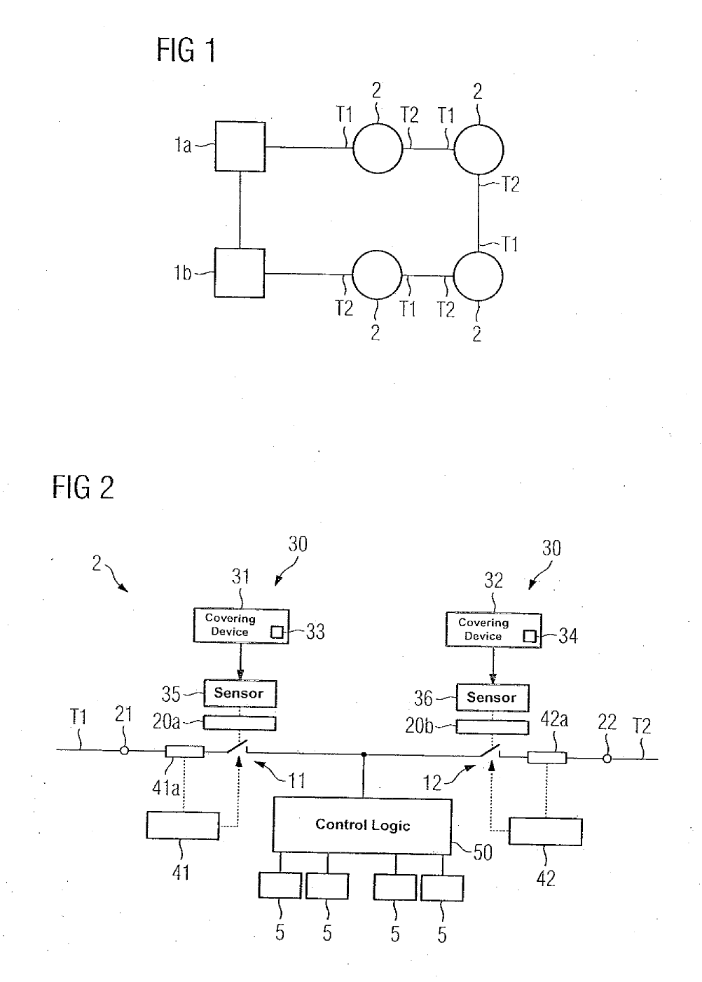

A connecting apparatus is described in more detail schematically in FIG. 2. On the left-hand side, the connecting apparatus 2 has an input terminal area 21, to which a first connecting line T1 can be connected. On the right-hand side, the connecting apparatus 2 has an output terminal area 22, to which a second connecting line T2 can be connected. The first connecting line T1, which has been connected in this way and the second connecting line T2, can be passed through over a first switching element 11 and a second switching element 12, such that current can flow from the first connecting line T1 through the input terminal area 21 to the second connecting line T2 through the output terminal area 22. Current can likewise flow, starting from the second connecting line T2 through the output terminal area 22, to the input terminal area 21 to the first connecting line T1. In order to operate a connecting apparatus 2 such as this in an explosion-hazard zone, it is necessary for the input terminal area 21 and the output terminal area 22 to be respectively protected by a first covering device 31 and a second covering device 32. The first covering device 31 has a first magnet 33, and the second covering device 32 has a second magnet 34. The magnets 33, 34 interact with a first sensor device 35 and a second sensor device 36. The first and second sensor devices 35, 36 comprise Hall sensors. Consequently, when the first covering device 31 is opened, the first magnet 33 is moved away from the first sensor device 35, which can thus initiate a signal that is passed on to a first control unit 20a. Here, the first control unit 20a is configured to operate the first switching element 11, and can thus disconnect the circuit between the input terminal area 21 and the output terminal area 22. Analogously to this disconnection of the circuit on one side by the first switching element 11, the output-side circuit can likewise be disconnected by the second switching element 12 by the second sensor device 36 and the second control unit 20b. Control logic for field devices 50 is provided for the connection of field devices 5.

For the subsequent analysis, it is necessary to consider three connecting apparatuses 2 of identical design, connected in series. This involves a center connecting apparatus, a predecessor connecting apparatus and a successor connecting apparatus. By way of example, it is intended to detach the first connecting line T1 for the center connecting apparatus at the input terminal area 21, for maintenance reasons. For this purpose, the first covering device 31 on the center connecting apparatus is opened, as a result of which the first control unit 20a receives a signal, and the circuit is disconnected by the switching element 11. The predecessor connecting apparatus is connected to the input terminal area 21 of the center connecting apparatus. When the circuit is disconnected by the first switching element 11, current can also no longer flow in the predecessor connecting apparatus. A first measurement device 41 and a first resistor 41a detect this lack of current flow in the predecessor connecting apparatus. This detection by the first measurement device 41 results in the first switching element 11 in the predecessor connecting apparatus likewise being operated. This operation likewise results in the circuit being opened. This ensures that, on the one hand, current can no longer flow through the open first switching element 11 in the center connecting apparatus, and current can also likewise no longer flow through the open switching element 11 in the predecessor connecting apparatus, i.e., the input terminal area 21 of the center connecting apparatus is switched to be free of voltage from the predecessor connecting apparatus.

The configuration and the procedure of the output terminal area 22 may be considered to be analogous to the switching of the input terminal area 21 to be free of voltage, as already described. The second switching element 12 is operated by the opening of the second cover device 32, and disconnects the circuit to the input terminal area 22. This disconnection of the circuit can be perceived by a lack of current flow in the successor connecting apparatus. This lack of current flow can in turn be detected by a measurement device in the successor connecting apparatus, and the detection also allows disconnection of the circuit in the successor connecting apparatus. The center connecting apparatus is now switched to be free of voltage on both sides via its respective predecessor connecting apparatus and its successor connecting apparatus. This therefore allows work to be carried safely on the terminal area in an explosion-hazard zone environment.

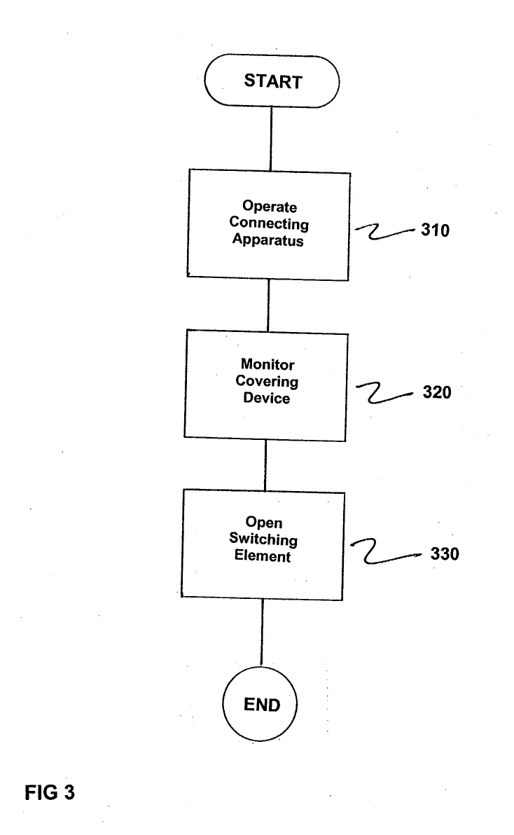

FIG. 3 is a flow chart of the method for operating a connecting apparatus for field devices in an explosion-hazard zone. The method comprises operating the connecting apparatus within a redundant communication ring with further connecting apparatuses, as indicated in step 310. Here, a first connecting line is connected by an input terminal area and a second connecting line is connected by an output terminal area such that the connecting apparatus is supplied with current by a feed device within the communication ring, where a covering device is provided for protection of at least one of the input terminal area and the output terminal area. A first sensor device monitors the covering device to detect opening of the covering device, as indicated in step 320. A first switching element is opened to interrupt the flow of the current from the input terminal area to the output terminal area when the first sensor device detects that the covering device has been opened, as indicated in step 330.

Thus, while there are shown, described and pointed out fundamental novel features of the invention as applied to preferred embodiments thereof, it will be understood that various omissions and substitutions and changes in the form and details of the illustrated apparatus, and in its operation, may be made by those skilled in the art without departing from the spirit of the invention. Moreover, it should be recognized that structures shown and/or described in connection with any disclosed form or embodiment of the invention may be incorporated in any other disclosed or described or suggested form or embodiment as a general matter of design choice.

What is claimed is:

1. A connecting apparatus for field devices in an explosion-hazard zone, comprising:
an input terminal area for a first connecting line;
an output terminal area for a second connecting line;
a covering device configured to protect at least one of the first and second terminal areas;
a first switching element for passing an electric current from the input terminal area to the output terminal area;
a control unit configured to control and operate the first switching element; and
a first sensor device which detects opening of the covering device, the first sensor device being connected to the control unit.

2. The connecting apparatus as claimed in claim 1, further comprising:
a first measurement device for measuring the electric current, the measurement device being configured such that a determined first measured value is comparable with a limit value and undershooting of the limit value is identifiable, the measurement device being further configured such that a current flow between the input terminal area and the output terminal area is interruptable independently of the detection performed by the first sensor means based on the limit value being undershot.

3. The connecting apparatus as claimed in claim 1, wherein the covering device includes a first covering device arranged over the input terminal area, and a second covering device arranged over the output terminal area.

4. The connecting apparatus as claimed in claim 2, wherein the covering device includes a first covering device arranged over the input terminal area, and a second covering device arranged over the output terminal area.

5. The connecting apparatus as claimed in claim 3, further comprising:
a second sensor device;
wherein the first sensor device is associated with the first covering device, and the second sensor device is associated with the second covering device.

6. The connecting apparatus as claimed in claim 5, further comprising:
a second switching element arranged in series with the first switching element;
wherein the second sensor device is to the control unit, and wherein the control unit is further configured to operate the second switching element.

7. The connecting apparatus as claimed in claim 6, further comprising:
a second measurement device for measuring the electric current, the second measurement device being configured such that a determined second measured value is comparable with a limit value and undershooting of the limit value is identifiable, the second measurement device being further configured such that the current flow between the input terminal area and the output terminal area and the current flow between the output terminal area and the input terminal area is interruptable independently of the detection performed by the second sensor device based on the limit value being undershot.

8. The connecting apparatus as claimed in claim 3, wherein the first and second covering device each include a magnet which activates a Hall sensor.

9. A method for operating a connecting apparatus for field devices in an explosion-hazard zone, comprising:
operating the connecting apparatus within a redundant communication ring with further connecting apparatuses, a first connecting line being connected by an input terminal area and a second connecting line being connected by an output terminal area such that the connecting apparatus is supplied with current by a feed device within the communication ring, a covering device being provided for protection of at least one of the input terminal area and the output terminal area;
monitoring, by a first sensor device, the covering device to detect opening of the covering device; and
opening a first switching element to interrupt the flow of the current from the input terminal area to the output terminal area when the first sensor device detects that the covering device has been opened.

10. The method as claimed in claim 9, further comprising:
changing a flow of current to one of a predecessor connecting apparatus and a successor connecting apparatus by operating the further connecting apparatuses in a series circuit with the connecting apparatus with the covering device open; and
measuring the flow of current in one of the predecessor connecting apparatus and the successor connecting apparatus; and interrupting the flow of current from the input terminal area to the output terminal area of a respective one of the predecessor connecting apparatus and the successor connecting apparatus if a limit value is undershot.

11. The method as claimed in claim 9, further comprising:
supplying the connecting apparatuses from respective input terminal areas and from their respective output terminal areas.

12. The method as claimed in claim 10, further comprising:
supplying the connecting apparatuses from respective input terminal areas and from their respective output terminal areas.

13. The method as claimed in claim 9, wherein the covering device comprises a first covering device provided over the input terminal area and a second covering provided over the output terminal area, the method further comprising:
opening the first covering device to open the first switching element; and
opening the second covering device to open a second switching element.

14. The method as claimed in claim 10, further comprising:
opening the first and second switching elements to switch the connecting apparatus with the open covering device to free of voltage on at least one side if the undershot limit value is detected by the measurement device arranged in the one of the predecessor connecting apparatus and the successor connecting apparatus to allow safe perform of work on the input and output terminal areas.
